(19) United States
(12) Patent Application Publication
(10) Pub. No.: US 2025/0074672 A1
(43) Pub. Date: Mar. 6, 2025

(54) ACCOMMODATION BOX

(71) Applicant: YAZAKI CORPORATION, Tokyo (JP)

(72) Inventors: Hirotaka Kiyota, Makinohara-shi (JP); Takeshi Onoda, Makinohara-shi (JP); Toshinori Yamada, Makinohara-shi (JP)

(21) Appl. No.: 18/949,988

(22) Filed: Nov. 16, 2024

Related U.S. Application Data
(63) Continuation of application No. PCT/JP2023/036961, filed on Oct. 12, 2023.

(30) Foreign Application Priority Data
Nov. 7, 2022 (JP) 2022-177818

(51) Int. Cl. B65D 53/02; B65D 43/02; B65D 43/06

(52) U.S. Cl. CPC B65D 53/02; B65D 43/0202; B65D 43/065; B65D 2543/00194; B65D 2543/00564; B65D 2543/00972

(57) ABSTRACT

An accommodation box includes a main body portion that is able to accommodate an electronic component thereinside, and has an opening portion formed to connect an inside and an outside, a cover portion to be attached to the main body portion by covering the opening portion, and a packing member that is provided on the cover portion, arranged between the main body portion and the cover portion, and performs water stop between the main body portion and the cover portion, and the packing member is configured to perform water stop with being in contact with a side surface of a side wall of the main body portion formed along an attachment direction of the cover portion.

### CROSS-REFERENCE TO RELATED APPLICATION(S)

This application is a continuation application of International Application No. PCT/JP2023/036961 filed on Oct. 12, 2023 which claims the benefit of priority from Japanese Patent Application No. 2022-177818 filed on Nov. 7, 2022 and designating the U.S., the entire contents of which are incorporated herein by reference.

### BACKGROUND OF THE INVENTION

### 1. Field of the Invention

The present invention relates to an accommodation box.

### BACKGROUND

### 2. Description of the Related Art

As an accommodation box, for example, as described in Japanese Patent Application Laid-open No. 2001-25135, an accommodation member including a lid member openable and closable with respect to a casing has been conventionally known. In the accommodation member, a packing is arranged at a position of the lid member where the lid member abuts the casing, and by the packing, a water stop function between the casing and the lid member is ensured.

The above-described accommodation member has room for improvement in that the attachment of the lid member to the casing becomes difficult if waterproofness is improved. For example, in the above-described accommodation member, because waterproofness is ensured by fitting the casing with the packing provided in the lid member, in order to obtain high waterproofness, it is necessary to strongly press the lid member against the casing. Thus, strong force becomes necessary for the attachment of the lid member to the casing, and an attachment work of the lid member cannot be smoothly performed.

### SUMMARY OF THE INVENTION

In view of the foregoing, the object of the present invention is to provide an accommodation box that can smoothly perform attachment of a cover portion while ensuring waterproofness.

In order to achieve the above mentioned object, an accommodation box according to one aspect of the present invention includes a main body portion that is able to accommodate an electronic component thereinside, and has an opening portion formed to connect an inside and an outside; a cover portion to be attached to the main body portion by covering the opening portion; and a packing member that is provided on the cover portion, arranged between the main body portion and the cover portion, and performs water stop between the main body portion and the cover portion, wherein the packing member performs water stop with being in contact with a surface of the main body portion formed along an attachment direction of the cover portion, and wherein the cover portion includes a press portion that is formed at a position facing the packing member, and presses the main body portion to be inserted between itself and the packing member, toward the packing member.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is an exploded perspective view of an accommodation box according to an embodiment; FIG. 2 is an explanatory diagram of a packing member of the accommodation box according to the embodiment; FIG. 3 is a cross-sectional view of the accommodation box taken along III-III in FIG. 1;

FIG. 4 is a cross-sectional view of the accommodation box taken along III-III in FIG. 1, at a time of cover portion attachment;

FIG. 5 is an explanatory diagram of a comparative example;

FIG. 6 is an explanatory diagram of a modified example of an accommodation box according to the embodiment;

FIG. 7 is an explanatory diagram of a modified example of an accommodation box according to the embodiment;

FIG. 8 is an explanatory diagram of a modified example of an accommodation box according to the embodiment;

FIG. 9 is an explanatory diagram of a modified example of an accommodation box according to the embodiment; and

FIG. 10 is an explanatory diagram of a modified example of an accommodation box according to the embodiment.

### DETAILED DESCRIPTION OF THE PREFERRED EMBODIMENTS

An embodiment according to the present invention will be described in detail below based on the drawings. In addition, the present invention is not limited by the embodiment. Further, components in the following embodiment include the ones that can be replaced by those skilled in the art, and are easy, or the ones that are substantially identical.

### Embodiment

An accommodation box according to an embodiment of the present invention will be described.

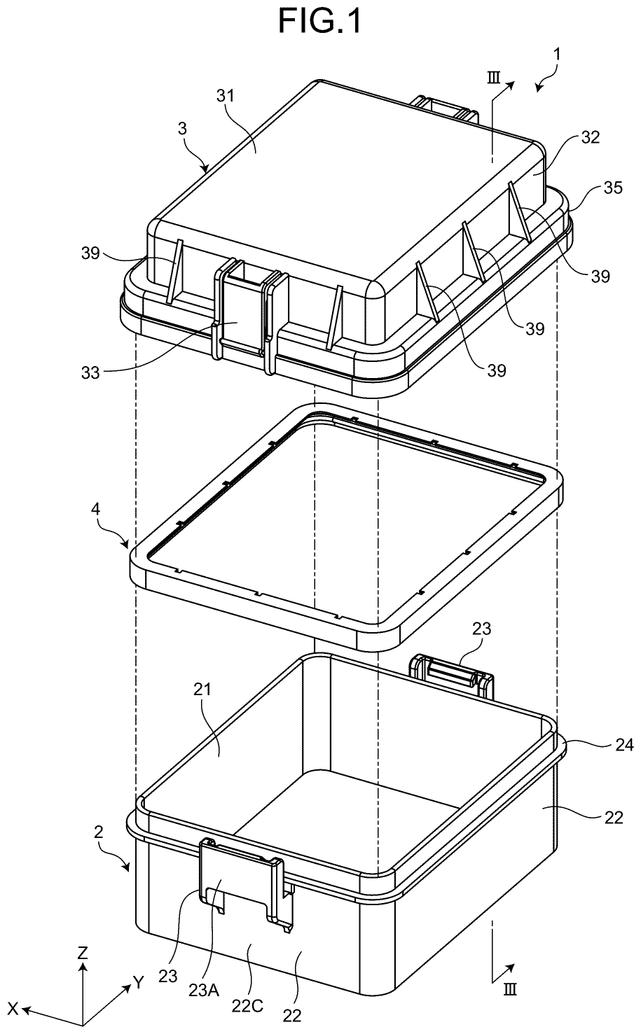

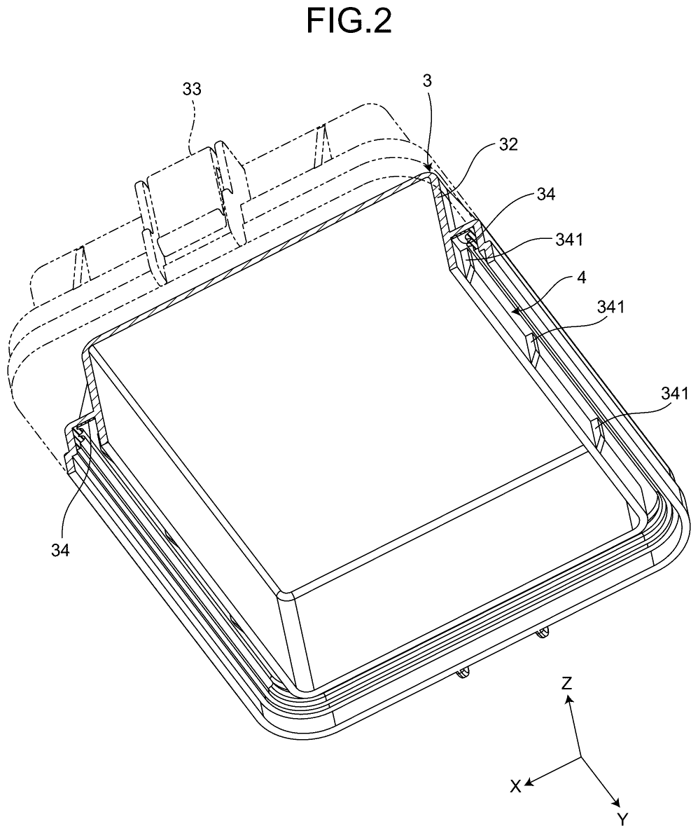

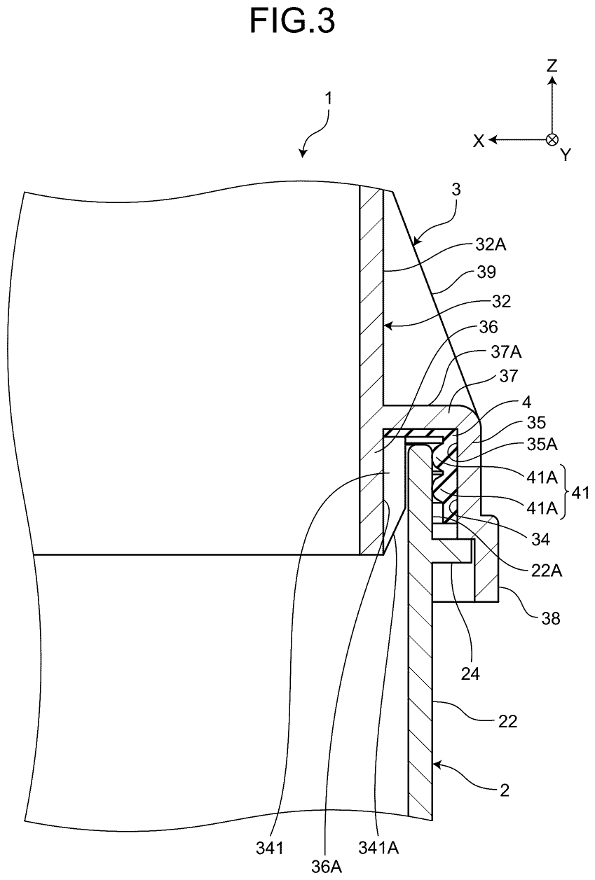

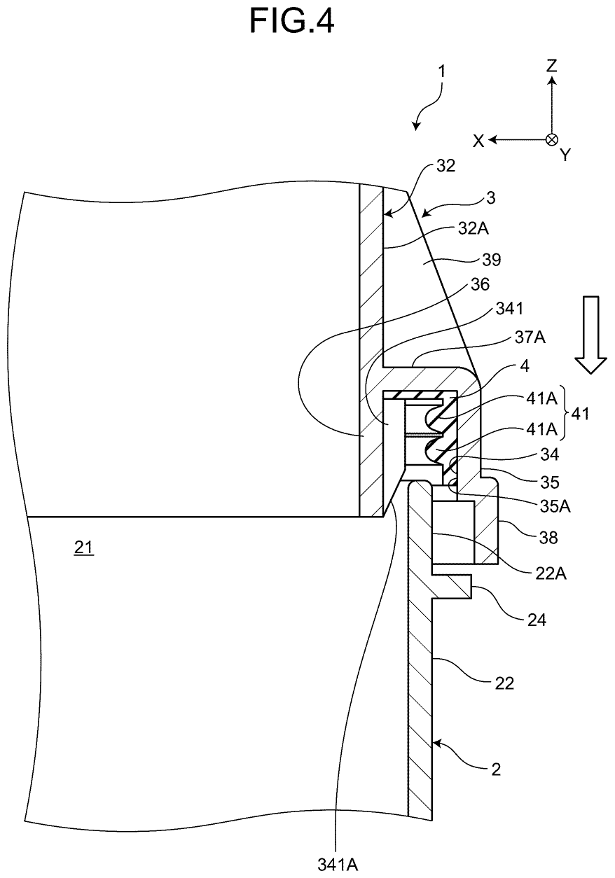

FIG. 1 is an exploded perspective view of an accommodation box according to an embodiment, and FIG. 2 is an explanatory diagram of a packing member of an accommodation box according to the embodiment. FIG. 3 is a cross-sectional view of the accommodation box taken along III-III in FIG. 1, and FIG. 4 is a cross-sectional view of the accommodation box taken along III-III in FIG. 1, at a time of cover portion attachment.

As illustrated in FIG. 1, an accommodation box 1 according to the present embodiment is a box member that accommodates an electronic component, for example, mounted on a vehicle, and used as an electric connection box that accommodates electronic components including a fuse and a relay. The accommodation box 1 includes a main body portion 2, a cover portion 3, and a packing member 4. The main body portion 2 is a body member with an opened top surface, and presents a rectangular cuboid shape, for example. The main body portion 2 can accommodate electronic components thereinside, and has an opening portion 21 formed on the top surface to connect the inside and the outside. The opening portion 21 of the main body portion 2 is closed by the cover portion 3 being attached. The opening portion 21 is an opening obtained by opening the entire top surface of the main body portion 2, for example.

On a side wall 22 of the main body portion 2, a latched portion 23 is provided. The side wall 22 is a wall portion forming a side surface of the main body portion 2, and the four side walls 22 are formed on the front, back, left, and right sides. The latched portion 23 is a portion to be latched onto a latch portion 33 of the cover portion 3. The latched portion 23 includes a latched piece 23A provided with being separated from a surface 22C on the outer side of the side wall 22. One latched portion 23 is provided at an upper position of each of the two facing side walls 22.

The cover portion 3 is an upper cover covering the opening portion 21 of the main body portion 2, and can be attached to the main body portion 2 by covering the opening portion 21. The cover portion 3 includes a top surface portion 31 and a hanging portion 32. The top surface portion 31 is a top surface portion of the cover portion 3, and has a shape adapted to the shape of the main body portion 2, such as a rectangular or a substantially rectangular shape, for example. The hanging portion 32 is a wall portion extending downward from the outer rim of the top surface portion 31, and is formed over the entire perimeter of the outer rim of the top surface portion 31. The cover portion 3 is provided with the latch portion 33. The latch portion 33 is a portion that holds the cover portion 3 on the main body portion 2 by engaging with the latched portion 23 of the main body portion 2, and performs holding release. The latch portion 33 is provided on a surface 32A on the outer side of the hanging portion 32, for example, and provided at the position corresponding to the latched portion 23. The latch portion 33 constitutes the lock mechanism together with the latched portion 23. The lock mechanism may be a lock mechanism with any structure as long as the cover portion 3 can be attached to and removed from the main body portion 2.

The packing member 4 is a water stop member that performs water stop between the main body portion 2 and the cover portion 3, and formed of resin. The packing member 4 is formed of resin with lower rigidity as compared with the cover portion 3, and formed of elastomeric resin such as elastomer, for example. The packing member 4 is provided by two-color molding, for example. More specifically, the packing member 4 is provided by two-color molding with the cover portion 3, and after the cover portion 3 is resin-molded, the packing member 4 is resin-molded using different resin.

As illustrated in FIG. 3, the packing member 4 is provided on the cover portion 3, arranged between the main body portion 2 and the cover portion 3, and stops water between the main body portion 2 and the cover portion 3. The packing member 4 performs water stop with being in contact with the surface of the main body portion 2 formed along an attachment direction (a Z direction in FIG. 3) of the cover portion 3. For example, the packing member 4 performs water stop with being in contact with a side surface 22A of the side wall 22 of the main body portion 2 formed in parallel with the attachment direction of the cover portion 3. Here, the parallel includes approximately parallel. The packing member 4 is provided in a groove 34 formed in the cover portion 3. The groove 34 is formed between an outer wall 35 and an inner wall 36 provided at a lower portion of the hanging portion 32. The hanging portion 32 branches to the inside and the outside in the lower portion to form the inner wall 36 and the outer wall 35. The inner wall 36 is a wall portion formed in the lower portion of the hanging portion 32. The outer wall 35 is a wall portion branching to the outer side via a protruding portion 37, is positioned on the outer side of the inner wall 36, and provided in parallel with the inner wall 36 at a predetermined distance from the inner wall 36. The protruding portion 37 is provided with protruding outward from the lower portion of the hanging portion 32, and causes the outer wall 35 to hang down from the leading end. In addition, an extension portion 38 is continuously formed below the outer wall 35. The extension portion 38 is a wall portion covering the outer side of the side wall 22 of the main body portion 2. The groove 34 is formed with being surrounded by the inner wall 36, the protruding portion 37, and the outer wall 35, to become a space having an opened lower side. The groove 34 is formed along an extending direction (a Y direction in FIG. 3) of the lower rim of the hanging portion 32.

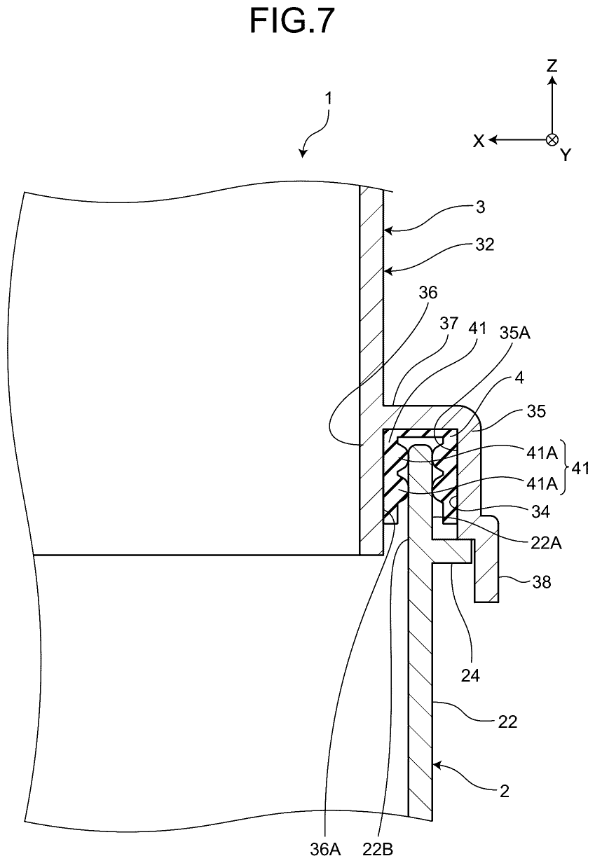

The packing member 4 includes a water stop portion 41 provided on an inner side surface 35A of the groove 34. The water stop portion 41 is a portion that performs water stop with being in contact with the side surface 22A of the side wall 22 of the main body portion 2 that is to be inserted into the groove 34. The water stop portion 41 includes a lip 41A that contacts the main body portion 2. The lip 41A is a protrusion with a mountain-shaped cross section, and protrudes toward the main body portion 2. For examples, two lips 41A are provided, and provided adjacently along an insertion direction (the Z direction in FIG. 3) of the main body portion 2. The lip 41A is formed along an extending direction (the Y direction in FIG. 3) of the inner side surface 35A, and has a protruding shape extending in the extending direction. The inner side surface 35A is a side surface on the inner side of the outer wall 35, and the water stop portion 41 and the lip 41A are formed on the outer side of the side wall 22 of the main body portion 2 that is to be inserted into the groove 34. That is, the water stop portion 41 is formed only on one side of the side wall 22 of the main body portion 2. As illustrated in FIG. 7, the water stop portions 41 are sometimes formed on both sides of the side wall 22, but here, the water stop portion 41 is provided in such a manner as to contact a side surface on one of the inner side and the outer side of the side wall 22 of the main body portion 2. Thus, because a portion that becomes an undercut in a case where the packing member 4 is resin-molded can be reduced, the mold release of the packing member 4 becomes easier and manufacturability becomes better. In addition, in a case where the packing member 4 is resin-molded, even if the position of a gate serving as a resin injection portion is set on a surface facing an end surface of the side wall 22, water stop can be performed without affecting a water stop function of the water stop portion 41. More specifically, even if a gate trace exists on the surface that the end surface of the side wall 22 faces, because there is no need to bring the end surface of the side wall 22 into contact with the packing member 4, the water stop function of the water stop portion 41 is not affected, and water stop between the main body portion 2 and the cover portion 3 can be ensured.

The cover portion 3 is provided with a press portion 341. The press portion 341 is a member that is formed at the position facing the packing member 4, and presses the main body portion 2 to be inserted between itself and the packing member 4, toward the packing member 4. For example, the press portion 341 is formed on an inner side surface 36A of the groove 34, and presses the main body portion 2 to be inserted into the groove 34, toward the water stop portion 41. Specifically, the press portion 341 is formed with protruding toward the water stop portion 41 from the inner side surface 36A of the inner wall 36, and presses the side wall 22 of the main body portion 2 toward the water stop portion 41 provided on the inner side surface 35A. A protrusion length of the press portion 341 is set in such a manner that a distance between the press portion 341 and the lip 41A of the water stop portion 41 becomes shorter than the thickness of the side wall 22 of the main body portion 2. With this configuration, the side wall 22 of the main body portion 2 can be pressed by the press portion 341 toward the lip 41A. In addition, a tapered surface 341A is formed in the lower portion of the press portion 341. The tapered surface 341A is a surface obtained by inclining the surface of the press portion 341 that faces the water stop portion 41, and inclines in such a manner that the protrusion length of the press portion 341 becomes smaller toward the lower side. That is, by the tapered surface 341A being formed, an entrance of the groove 34 becomes wider, and the side wall 22 of the main body portion 2 can be smoothly inserted toward the rear side of the groove 34. As illustrated in FIG. 2, for example, a plurality of the press portions 341 is formed at preset intervals in an extending direction (an X direction and a Y direction in FIG. 2) of the hanging portion 32. Note that the press portion 341 is sometimes provided on the main body portion 2 instead of the cover portion 3.

In FIG. 3, the cover portion 3 is provided with a reinforcement rib 39. The reinforcement rib 39 is a member that is provided with being bonded to the surface of the cover portion 3, and suppresses deformation of the outer wall 35 of the cover portion 3 at the position where the packing member 4 is provided. For example, the reinforcement rib 39 is provided with being bonded to the surface 32A of the hanging portion 32 and a surface 37A of the protruding portion 37 in the cover portion 3, and suppresses deformation of the outer wall 35. The reinforcement rib 39 is a triangular plate-like member, for example, and bonded to the surface 37A of the protruding portion 37 and the surface 32A of the hanging portion 32 that are orthogonal to each other, and suppresses the movement of the protruding portion 37 with respect to the hanging portion 32. This prevents the outer wall 35 and the extension portion 38 from deforming and moving with respect to the hanging portion 32. As illustrated in FIG. 1, for example, a plurality of the reinforcement ribs 39 is formed at preset intervals in the extending direction (an X direction and a Y direction in FIG. 1) of the hanging portion 32.

In FIG. 3, the side wall 22 of the main body portion 2 is provided with a protruding piece 24. The protruding piece 24 is a portion protruding from the side wall 22, and regulates the downward movement of the cover portion 3 by contacting the hanging portion 32 of the cover portion 3. The protruding piece 24 is formed at an upper position of the side wall 22, and is continuously formed over the entire perimeters of four side walls 22, for example. As illustrated in FIG. 3, the protruding piece 24 is formed on the outer surface of the side wall 22, and provided in such a manner as to contact a lower end of the outer wall 35. In this manner, by the protruding piece 24 contacting the outer wall 35, the groove 34 is closed by the protruding piece 24, and the entry of water or the like into the groove 34 from the outside is prevented.

Next, the attachment of a cover portion in an accommodation box according to the present embodiment will be described.

As illustrated in FIG. 1, the cover portion 3 is arranged in an upper portion of the opening portion 21 of the main body portion 2, and the attachment of the cover portion 3 is performed with respect to the main body portion 2 in such a manner that the cover portion 3 covers the opening portion 21. At this time, the cover portion 3 is arranged in such a manner as to align the position of the latch portion 33 of the cover portion 3 with the position of the latched portion 23 of the main body portion 2.

Then, as illustrated in FIG. 4, the cover portion 3 approaches from the upside of the main body portion 2, and the side wall 22 is inserted into the groove 34. At this time, the press portion 341 is provided in the groove 34, but because the tapered surface 341A is formed in the press portion 341, the side wall 22 is smoothly guided into the groove 34 without being caught by the press portion 341.

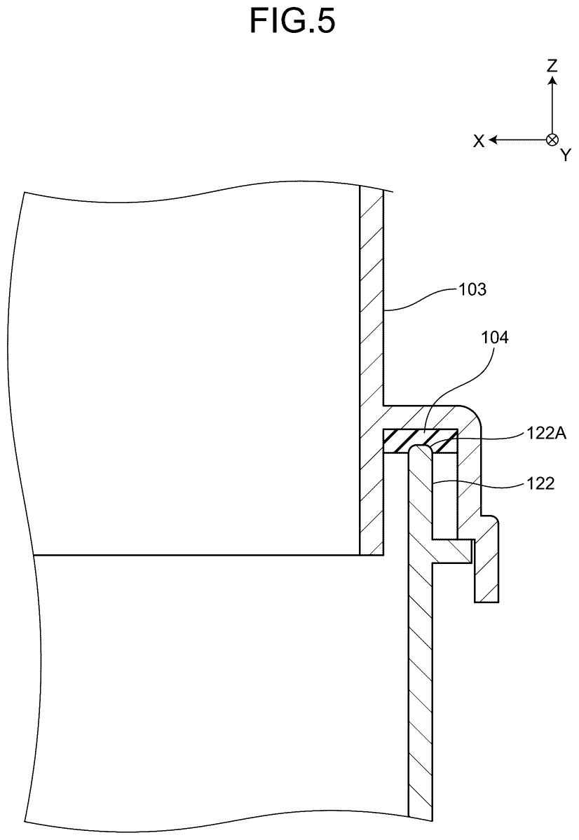

Then, in a state in which the lip 41A of the water stop portion 41 has contact with the side surface 22A of the side wall 22, and the lip 41A has contact with the side surface 22A, the side wall 22 is inserted toward the rear side of the groove 34. At this time, because a contact direction (an X direction in FIG. 4) of the water stop portion 41 is a direction intersecting with the attachment direction (a Z direction in FIG. 4) of the cover portion 3 instead of the same direction, the attachment of the cover portion 3 is smoothly performed. For example, if, as illustrated in FIG. 5, in a case where water stop is performed by causing an end surface 122A of a side wall 122 to abut a packing 104, an attachment direction (a Z direction in FIG. 5) of a cover portion 103 and a contact direction (a Z direction in FIG. 5) of the packing 104 become the same direction, waterproofness cannot be improved unless the cover portion 103 is strongly pressed against the packing 104, and strong attachment force becomes necessary for the attachment of the cover portion 103. In contrast to this, in the accommodation box 1 according to the present embodiment, because the attachment direction of the cover portion 3 and the contact direction of the water stop portion 41 are intersecting directions instead of being the same direction, strong attachment force becomes unnecessary in the attachment of the cover portion 3. Accordingly, the accommodation box 1 according to the present embodiment can smoothly perform attachment of the cover portion 3 while ensuring waterproofness of the main body portion 2 and the cover portion 3.

Then, as illustrated in FIG. 3, the hanging portion 32 contacts the protruding piece 24, and the cover portion 3 is fitted with the main body portion 2. In other words, the lower end of the outer wall 35 contacts the protruding piece 24, and the insertion of the side wall 22 into the groove 34 is completed. At this time, because the side wall 22 of the main body portion 2 is pressed by the press portion 341 against the water stop portion 41, waterproofness between the main body portion 2 and the cover portion 3 can be improved. For example, if, in a case where the press portion 341 is not formed, the side wall 22 might deform to collapse in such a manner as to get away from the water stop portion 41 (the side wall 22 might collapse toward the left side in FIG. 3), and waterproofness is expected to fail to be ensured. In contrast to this, in the accommodation box 1 according to the present embodiment, such deformation of the side wall 22 is suppressed, and water stop can be performed by surely pressing the water stop portion 41 against the side wall 22.

In addition, in the accommodation box 1 according to the present embodiment, by the reinforcement rib 39 being provided, the outer wall 35 and the extension portion 38 are prevented from deforming in such a manner as to open toward the outer side. Thus, a decline in waterproofness of the main body portion 2 and the cover portion 3 is suppressed. For example, if, in a case where the reinforcement rib 39 is not provided, by water pressure being added from the lower side of the extension portion 38 or by the side wall 22 pressing the outer wall 35 via the water stop portion 41, the outer wall 35 and the extension portion 38 might deform to open toward the outer side. In contrast to this, in the accommodation box 1 according to the present embodiment, it is possible to suppress deformation of the outer wall 35 and the extension portion 38 using the reinforcement rib 39, and suppresses a decline in waterproofness of the main body portion 2 and the cover portion 3.

In addition, because the water stop portion 41 is brought into contact with the side surface 22A of the side wall 22 in the accommodation box 1 according to the present embodiment, a contact area can be made wide, and improvement in waterproofness can be achieved. For example, if, as illustrated in FIG. 5, in a case where water stop is performed by causing the end surface 122A of the side wall 122 to abut the packing 104, because a length of the end surface 122A (in FIG. 5, a length in an X direction) becomes narrower, a contact area between the side wall 122 and the packing 104 becomes narrower. Accordingly, it is difficult to improve waterproofness. In contrast to this, in the accommodation box 1 according to the present embodiment, a contact area between the side wall 22 and the water stop portion 41 can be made wider, and waterproofness can be improved.

Then, after the cover portion 3 is fitted with the main body portion 2, the latch portion 33 is latched by the latched portion 23. The attachment of the cover portion 3 is thereby completed.

As described above, according to the accommodation box 1 according to the present embodiment, because water stop is performed with the packing member 4 being brought into contact with the surface of the main body portion 2 formed along the attachment direction of the cover portion 3, strong force is not required for the attachment of the cover portion 3, and water stop function between the main body portion 2 and the cover portion 3 can be ensured by the water stop portion 41. Accordingly, the accommodation box 1 according to the present embodiment can smoothly perform attachment of the cover portion 3 while ensuring waterproofness.

In addition, the accommodation box 1 according to the present embodiment can press the main body portion 2 toward the water stop portion 41 by the press portion 341 being formed in the groove 34. Thus, waterproofness between the main body portion 2 and the cover portion 3 can be improved.

In addition, the accommodation box 1 according to the present embodiment can suppress outward deformation of the outer wall 35 by the reinforcement rib 39 being provided. Thus, a decline in the water stop function of the main body portion 2 and the cover portion 3 can be suppressed.

In addition, because the accommodation box 1 according to the present embodiment performs water stop by inserting the main body portion 2 into the groove 34 between the inner wall 36 and the outer wall 35, and bringing the packing member 4 provided on at least one of the inner wall 36 and the outer wall 35, into contact with the side surface 22A of the main body portion 2, strong force is not required for the attachment of the cover portion 3, and water stop function between the main body portion 2 and the cover portion 3 can be ensured using the water stop portion 41. Accordingly, the accommodation box 1 according to the present embodiment can smoothly perform attachment of the cover portion 3 while ensuring waterproofness.

In addition, in the accommodation box 1 according to the present embodiment, the water stop portion 41 of the packing member 4 is formed only on a side surface of the inner wall 36 or the outer wall 35. Thus, a portion that becomes an undercut in a case where the packing member 4 is resin-molded can be reduced. Accordingly, in the accommodation box 1 according to the present embodiment, the mold release of the packing member 4 becomes easier and manufacturability can be improved.

Note that, an accommodation box according to an embodiment has been described above, but an accommodation box according to the present invention is not limited to the above-described embodiment, and various changes can be made within the scope set forth in the appended claims. In addition, the accommodation box according to the present embodiment may be formed by appropriately combining the components of the embodiment and the modified example described above.

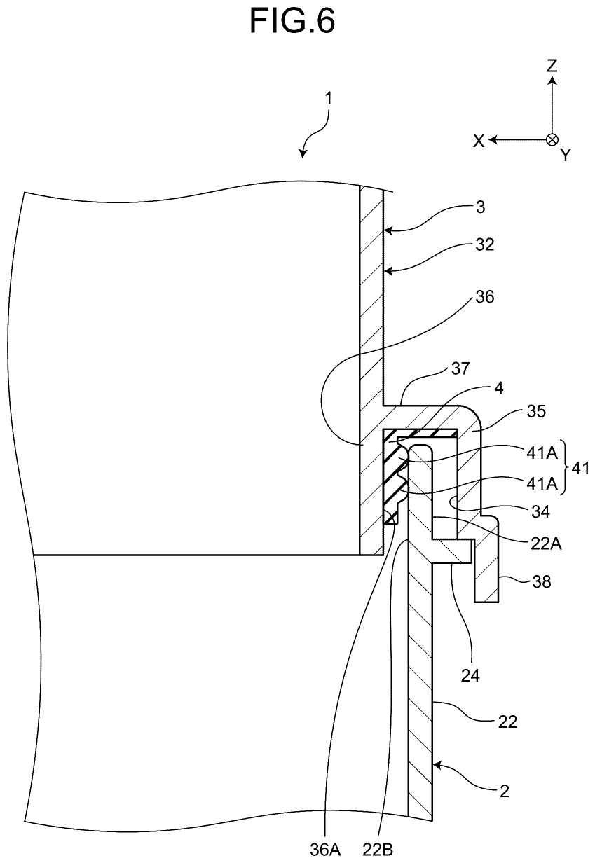

For example, in the above-described embodiment, the description has been given of a case where water stop is performed with the water stop portion 41 of the packing member 4 being in contact with the side surface 22A on the outer side of the side wall 22 of the main body portion 2, but as illustrated in FIG. 6, water stop may be performed with the water stop portion 41 being in contact with a side surface 22B on an inner side of the side wall 22. For example, the water stop portion 41 is provided on the inner side surface 36A of the inner wall 36, and performs water stop with being in contact with the side surface 22B of the side wall 22. Also in this case, a function effect similar to that of the accommodation box 1 according to the above-described embodiment can be obtained. Note that, in this case, the press portion 341 may be provided with being protruded from the inner surface of the outer wall 35.

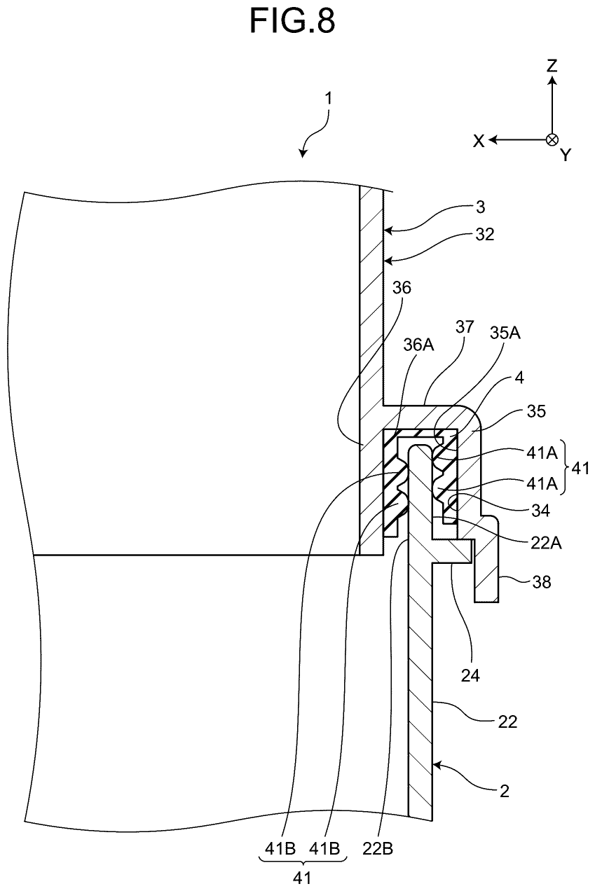

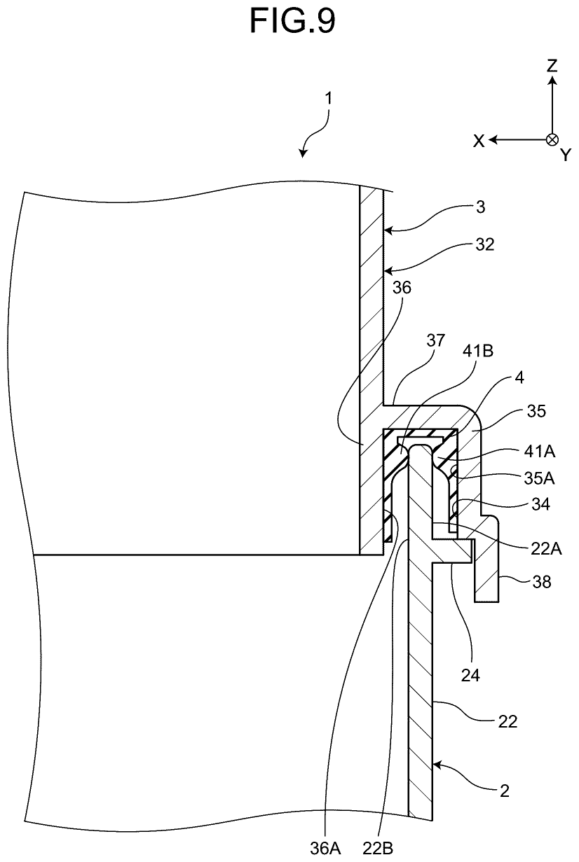

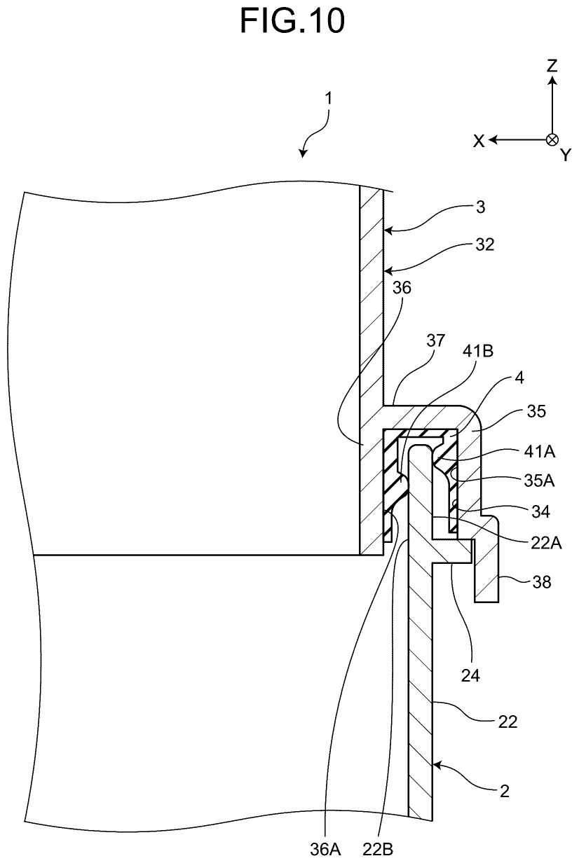

In addition, in the above-described embodiment, the description has been given of a case where water stop is performed with the water stop portion 41 of the packing member 4 being in contact only with the side surface 22A on one side of the side wall 22 of the main body portion 2, but as illustrated in FIG. 7, water stop may be performed with the water stop portions 41 being in contact with the side surface 22A and the side surface 22B on both sides of the side wall 22. In addition, as illustrated in FIG. 8, between the lip 41A that contacts the side surface 22A, and a lip 41B that contacts the side surface 22B, a position in the height direction Z may be varied. In FIG. 8, as compared with FIG. 7, mold release in resin molding of the packing member 4 becomes easier. In addition, as illustrated in FIGS. 9 and 10, one lip 41A that contacts the side surface 22A, and one lip 41B that contacts the side surface 22B may be formed. In FIGS. 9 and 10, because a portion that becomes an undercut is reduced as compared with FIG. 7, mold release in resin molding of the packing member 4 becomes easier. In addition, in FIG. 10, because a position in the height direction Z is varied between the lip 41A that contacts the side surface 22A, and the lip 41B that contacts the side surface 22B, as compared with FIG. 9, mold release in resin molding of the packing member 4 becomes easier. Then, also in the cases of FIGS. 7 to 10, a function effect almost similar to that of the accommodation box 1 according to the above-described embodiment can be obtained. For example, because the water stop portion 41 of the packing member 4 performs water stop with being in contact with the side surface of the main body portion 2, strong force is not required for the attachment of the cover portion 3, and water stop function between the main body portion 2 and the cover portion 3 can be ensured using the water stop portion 41. Accordingly, it is possible to smoothly perform attachment of the cover portion 3 while ensuring waterproofness.

In addition, in the above-described embodiment, a case where an accommodation box is applied to an electric connection box that is mounted on a vehicle and accommodates electronic components has been described, but the accommodation box according to the present invention may be applied to an accommodation box not mounted on a vehicle.

According to the accommodation box according to the present embodiment, it is possible to smoothly perform attachment of a cover portion while ensuring waterproofness.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An accommodation box comprising:
a main body portion that is able to accommodate an electronic component thereinside, and has an opening portion formed to connect an inside and an outside;
a cover portion to be attached to the main body portion by covering the opening portion; and
a packing member that is provided on the cover portion, arranged between the main body portion and the cover portion, and performs water stop between the main body portion and the cover portion,
wherein the packing member performs water stop with being in contact with a surface of the main body portion formed along an attachment direction of the cover portion, and
wherein the cover portion includes a press portion that is formed at a position facing the packing member, and presses the main body portion to be inserted between itself and the packing member, toward the packing member.

2. The accommodation box according to claim 1,
wherein the cover portion includes a reinforcement rib that is bonded to a surface of the cover portion, and suppresses deformation of a wall portion of the cover portion on which the packing member is provided.

3. An accommodation box comprising:
a main body portion that is able to accommodate an electronic component thereinside, and has an opening portion formed to connect an inside and an outside;
a cover portion to be attached to the main body portion by covering the opening portion; and
a packing member that is provided on the cover portion, arranged between the main body portion and the cover portion, and performs water stop between the main body portion and the cover portion,
wherein the packing member performs water stop with being in contact with a surface of the main body portion formed along an attachment direction of the cover portion, and
wherein the cover portion includes a reinforcement rib that is bonded to a surface of the cover portion, and suppresses deformation of a wall portion of the cover portion on which the packing member is provided.

4. The accommodation box according to claim 1,
wherein the cover portion includes a hanging portion hanging downward from an outer rim of a top surface portion,
the hanging portion forms an inner wall and an outer wall by branching a lower portion to an inside and an outside, and inserts the main body portion into a groove
between the inner wall and the outer wall, and the packing member includes a water stop portion provided on at least one inner side surface of the inner wall or the outer wall, and performs water stop by bringing the water stop portion into contact with the surface of the main body portion that is to be inserted into the groove.

5. The accommodation box according to claim 3,
wherein the cover portion includes a hanging portion hanging downward from an outer rim of a top surface portion,
the hanging portion forms an inner wall and an outer wall by branching a lower portion to an inside and an outside, and inserts the main body portion into a groove between the inner wall and the outer wall, and
the packing member includes a water stop portion provided on at least one inner side surface of the inner wall or the outer wall, and performs water stop by bringing the water stop portion into contact with the surface of the main body portion that is to be inserted into the groove.

6. The accommodation box according to claim 4,
wherein the water stop portion is formed only on the one inner side surface of the inner wall or the outer wall.

7. The accommodation box according to claim 5,
wherein the water stop portion is formed only on the one inner side surface of the inner wall or the outer wall.
